(19) United States
(12) Patent Application Publication
(10) Pub. No.: US 2012/0158344 A1
(43) Pub. Date: Jun. 21, 2012

(54) DEGRADATION DETERMINATION

(76) Inventors: Armin HIMMELSTOSS, Weissach Im Tal (DE); Andreas HEINTZE, Boeblingen (DE)

(21) Appl. No.: 13/315,094

(22) Filed: Dec. 8, 2011

(30) Foreign Application Priority Data
Dec. 21, 2010 (DE) 102010063761.0

(51) Int. Cl. G06F 19/00; G01R 31/04

(52) U.S. Cl. 702/108; 324/538

(57) ABSTRACT

An electrical device includes connectors for an electrical connection to a voltage source, a sampling device for determining a voltage applied to the connectors, a controllable load for changing an electrical power consumption of the device at the connectors, and a control device, which is configured for the purpose of determining a degradation of the electrical connection if voltages, which are applied to the connectors at different electrical power consumptions, differ from one another by more than a predetermined amount.

### CROSS REFERENCE

The present application claims the benefit under 35 U.S.C. §119 of German Patent Application No. 102010063761.0 filed on Dec. 21, 2010, which is expressly incorporated herein by reference in its entirety.

### FIELD OF THE INVENTION

The present invention relates to an electrical device and a method for detecting a degradation of an electrical connection between the device and a voltage source.

### BACKGROUND INFORMATION

In systems of multiple electrical devices which are connected to one another, electrical connections between the devices are frequently subjected to stresses, which may reduce the line quality of the electrical connections. For example, an electrical connection between two control units on a motor vehicle may be subjected to mechanical, thermal, and chemical stresses. These stresses may result in one of the devices not working properly. It is frequently not possible to clearly reproduce the circumstances under which an error occurs, so that in the case of an error, for safety reasons, more elements are often replaced than would actually be necessary.

Conventionally, electrical devices which are interconnected with one another on board a motor vehicle, are equipped with diagnostic functions, so that errors in one of the electrical components may be collected and analyzed at a central location. For example, a driver of the motor vehicle may be informed of the existence of the error and circumstances of the error may be stored in an error memory, in order to be able to localize the causes of the error more precisely in a repair shop.

German Patent Application No. DE 10 2005 046 282 A1 describes a device for error current recognition in an electronic device, insulation of a conductor, which fulfills its purpose only inadequately, being detected when a current flows between the conductor and another conductor in the area of the insulation.

In general, it is desirable to determine an error even before or during its occurrence, in order to be able to remedy it before the cause of the error results in further errors. It is an object of the present invention to provide an electrical device which is configured for the purpose of determining a degradation of an electrical connection between an electrical device and a voltage source. Furthermore, it is an object of the present invention to provide a method for determining the degradation of the electrical connection.

### SUMMARY

According to a first aspect, the present invention relates to an electrical device having connectors for an electrical connection to a voltage source, a sampling device for determining a voltage applied to the connectors, a controllable load for changing an electrical power consumption of the device at the connectors, and a control device, which is configured for the purpose of determining a degradation of the electrical connection, if the voltages applied to the connectors differ from one another by more than a predetermined amount in the event of different electrical power consumptions.

It may be advantageously determined whether there is a degradation of the electrical connection at a point in time at which a malfunction of the electrical device has not yet occurred. In particular, an insidious degradation of the electrical connection may be established by the device in a timely manner.

The electrical connection may include a plug connection and the degradation may be a corrosion of the plug connection. Plug connections are widespread in the automotive environment, in particular, for reasons of installation and maintenance. A corrosion of the plug connection may progress more or less insidiously due to shocks, gasoline, oil, salt, heat, cold, and moisture.

The electrical connection may also include an electromechanical interruption element and the degradation may include wear of the interruption element. For example, a mechanically operated switch may be subjected to contact erosion. Oxide layers and other contaminants may form on the switch, which obstruct a current flow through the switch. The contacts of the switch may also be deformed by the contact erosion to such an extent that the switch no longer completely opens or closes. The interruption element may accordingly also be a commutator, for example, of a generator or an electric motor.

The controllable load preferably includes a switchable electrical resistor. The power consumption of the device is thus cost-effectively controllable at a predetermined value, so that predetermined power consumptions are generatable on the connectors of the device. The electrical resistor may be installed in the device or may be situated outside the device, for example, to dissipate heat arising in the area of the resistor.

The controllable load preferably includes a function element of the device, which is provided in any case and may be switched on or off as needed. In particular, the device may be a radar sensor for use on a motor vehicle and the electrical resistor may include an electrical heater of a heatable radar lens of the radar sensor. An existing radar sensor may thus be used according to the present invention with relatively minor changes, allowing design and manufacturing expenditures for the device to be reduced.

According to a second aspect, the present invention relates to a method for detecting a degradation of an electrical connection between a voltage source and connectors of an electrical device. The method includes steps of determining a first voltage, which is applied to the connectors of the electrical device, changing an electrical power consumption of the device at the connectors, determining a second voltage which is applied to the connectors of the electrical device, and determining the degradation if the voltages differ from one another by more than a predetermined amount.

The example method may advantageously be used with little effort on a variety of electrical devices, which offer the requirements for executing the method. This applies in particular to electrical control units, which are controllable with the aid of an integrated programmable microcomputer.

The voltages are preferably converted into a digital form and compared to one another in the digital form. Complex analog storage of the first voltage until the second voltage is available for the comparison may thus be avoided. In addition, further processing of the two voltages in their digital forms may be more rapid and precise.

The example method may be triggered by various procedures. For example, the method may be carried out after a signal, which triggers the method, has been received from a control unit connectable to the device. Alternatively or additionally, the method may be executed in a time-controlled manner, i.e., for example, at fixed time intervals during a service life of the device. Furthermore, the method may additionally or alternatively be triggered in an event-controlled manner, for example, whenever the device is put into operation. Combinations are also possible, for example, triggering after a predetermined time after a predetermined event.

The example method preferably includes a final step of outputting a signal, which indicates the degradation, to another control unit. This control unit may be identical to the control unit which has sent the signal to carry out the method. Central error handling is made possible by outputting the signal indicating the degradation. A specific degradation of the electrical connection may thus be correlated with another event, for example, a degradation of another electrical connection, allowing the location of the electrical connection at which the degradation occurs to be specified with improved precision.

According to a third aspect, the present invention relates to a computer program product having program code for carrying out the specified method when it runs on a processing unit or is stored on a computer-readable data carrier.

### BRIEF DESCRIPTION OF THE DRAWINGS

The present invention is described in greater detail below with reference to the figures.

FIG. 1 shows an electrical device on board a motor vehicle.

FIG. 2 shows a flow chart of an example method in the device from FIG. 1.

### DETAILED DESCRIPTION OF EXAMPLE EMBODIMENTS

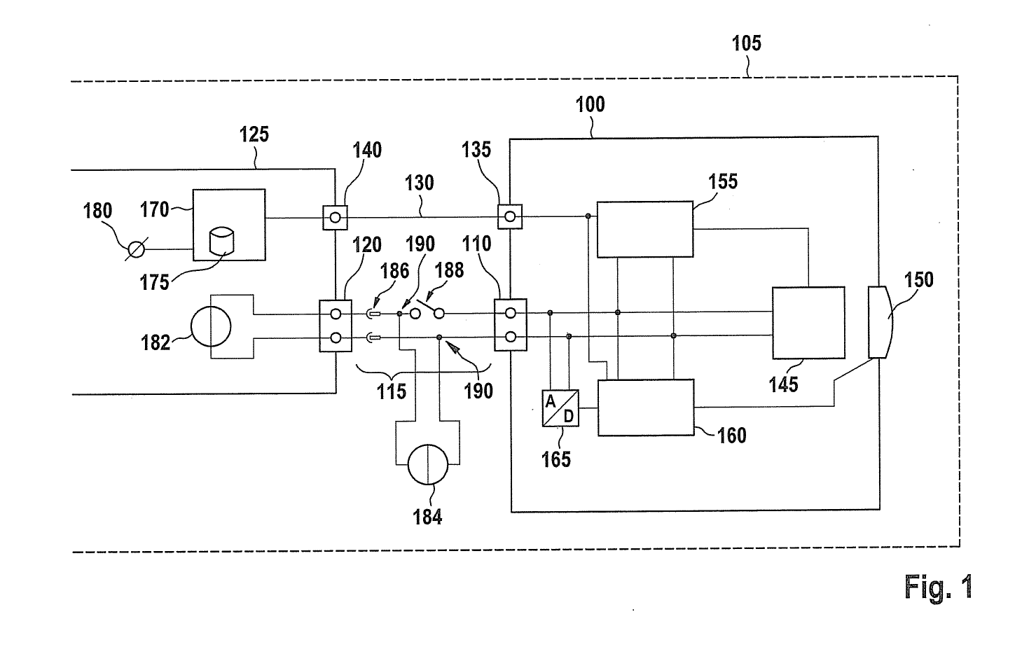

FIG. 1 shows a schematic diagram of an electrical device 100 on board a motor vehicle 105. In the illustration of FIG. 1, device 100 is a radar sensor for determining a distance to an object at a distance from a motor vehicle 105.

However, in alternative specific embodiments, device 100 may also be a different device, in particular a control unit, a sensor, or an electrical actuator. The device may be used on board motor vehicle 105 or in an airplane, airship, or spaceship, a construction vehicle, a construction machine, a rail vehicle, an automation technology system, a control console, in power plant technology, in a monitoring or safety-relevant electrical system of a nuclear power plant or a research device, on a military vehicle, or a military device. As explained below, in addition to general plug connections, lines, and ground points, which may develop increased transition resistances because of corrosion and/or mechanical degradation, electrical device 100 may be used to monitor switches, relays, commutators, frequently plugged plug connectors or insertion systems having backplane plug connectors, for example, with regard to the formation of undesired increased transition resistances.

Device 100 includes a pair of connectors 110, which are connected with the aid of an electrical connection 115 to a pair of connectors 120 of a control unit 125. Furthermore, there is a communication connection 130 between a connector 135 of device 100 and a connector 140 of control unit 125.

Device 100 includes a radar sensor 145, a heatable radar lens 150, a sensor control system 155, a control device 160, and an analog-digital converter 165.

Connectors 110 of device 100 are internally electrically connected to radar sensor 145, sensor control system 155, control device 160, and analog-digital converter 165. Furthermore, connector 135 for communication connection 130 is connected inside device 100 to sensor control system 155 and control device 160. Control device 160 is additionally connected to heatable radar lens 150 and analog-digital converter 165. There is a further connection between radar sensor 145 and sensor control system 155.

Control unit 125 may include a processing unit 170, which is connected to connector 140 for communication connection 130. Processing unit 170 may further include an error memory 175. In addition, processing unit 170 may be connected to an interface 180 to output a signal to a driver of motor vehicle 105 or another control component. Furthermore, control unit 125 may include a first voltage source 182, which is connected to connectors 120 for electrical connection 115. In an alternative specific embodiment, control unit 125 and device 100 may be supplied with voltage with the aid of a second voltage source 184, which is connected to electrical connection 115 between connectors 110 and 120.

Electrical connection 115 may include a plug connection 186. Plug connection 186 may include connectors 120 of control unit 125 or connectors 110 of device 100. Furthermore, a switch 188 may be provided for interrupting electrical connection 115. If second voltage source 184 is used, contact points 190 may exist where second voltage source 184 is connected to electrical connection 115.

If switch 188 is closed, a voltage, which corresponds to the voltage of first voltage source 182 or the voltage of second voltage source 184, is typically applied to connectors 110. In particular, electrical transitions of electrical connection 115, specifically connectors 110 and 120, plug connections 186, switch 188, and contact points 190, offer attack surfaces for contamination, wear, and corrosion. Influences of this type may act mechanically on electrical connection 115 and an electrical resistance between power source 182 or 184 and connectors 110 of device 100 may increase.

As long as a power consumption of device 100 is relatively small, the voltage applied to connectors 110 of device 100 is less than the voltage of first voltage source 182 or second voltage source 184 only by a small amount. However, if the power consumption of device 100 increases because an internal component of device 100 is activated, the voltage applied to connectors 110 may collapse due to the resistance of electrical connection 115 and may be significantly less than the voltage provided by power source 182 or 184. Proper functioning of device 100 may no longer be ensured.

In order to determine whether there is a degradation of electrical connection 115, control device 160 is configured for the purpose of determining the voltage applied to connectors 110 of device 100 under two different power consumptions of device 100 with the aid of analog-digital converter 165. A change of power consumption 100 is induced by activating an electrical consumer in the form of heatable radar lens 150 in device 100. In an alternative specific embodiment, control device 160 may also bring about a shutdown of a component of device 100, in order to induce the change of the power consumption of device 100 in the form of a reduction of the absorbed power.

The voltages, which are sampled with the aid of analog-digital converter 165 at different power consumptions of device 100 and are digitized with the aid of analog-digital converter 165, are numerically compared to one another by control device 160. If the difference between the determined voltages exceeds a predetermined amount, control device 160 is configured for the purpose of determining a degradation of electrical connection 115. In this case, a determination result may be transmitted from control device 160 of device 100 to control unit 125 with the aid of communication connection 130.

In one specific embodiment, sensor control system 155 and control device 160 are combined. In another specific embodiment, the voltages sampled by analog-digital converter 165 are transmitted with the aid of communication connection 130 to processing unit 170 of control unit 125. The numerical comparison of the voltages and the determination of whether a difference between the two voltages exceeds the predetermined amount are then carried out by processing unit 170.

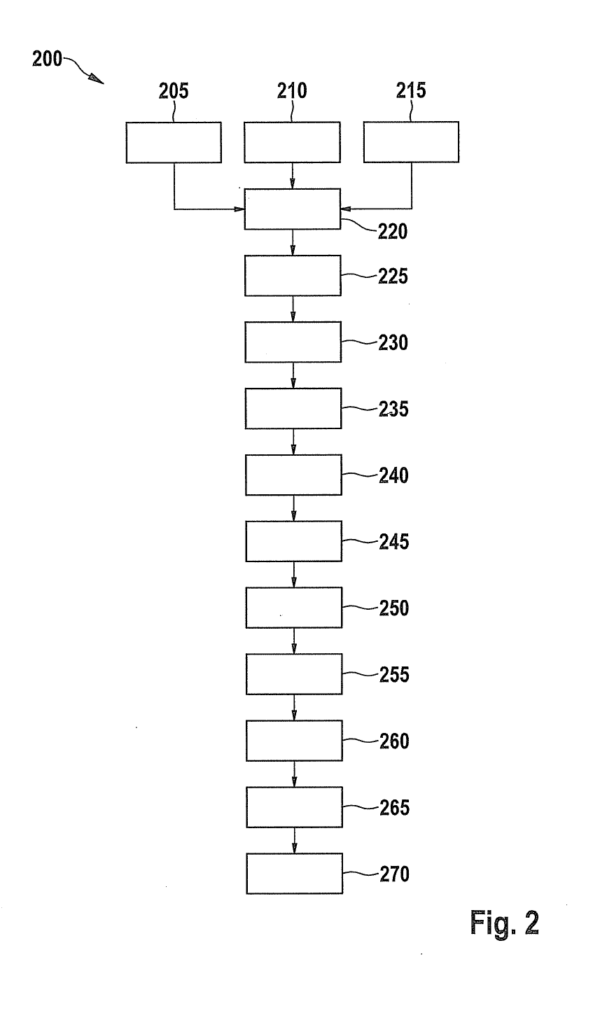

FIG. 2 shows a flow chart of a method 200 for determining the degradation of electrical connection 115 in FIG. 1. Method 200 is preferably performed on control device 160 of device 100, furthermore, processing unit 170 preferably being a programmable microcomputer.

Method 200 may be initiated by one of steps 205, 210, or 215. In step 205, using communication connection 130, control unit 125 requests that device 100 check electrical connection 115 for degradation. In step 210, the check is initiated on the part of device 100 based on a determination over time. The check may be carried out periodically at fixed intervals, for example. In step 215, the check is initiated on the part of device 100 in an event-based manner. Such an event may include start-up of device 100. The start-up is typically determinable by supplying device 100 with an electrical voltage via connectors 110.

Steps 205, 210, and 215 are not mutually dependent; the following determination of the degradation according to the method may be initiated in any of the three different ways or also a combination thereof.

A first voltage at connectors 110 of device 100 is determined in a step 220. Subsequently, the first voltage is converted into a digital value in a step 225 and stored in digital form in a step 230. Some or all of steps 220 to 230 may also take place in a specific embodiment of the present invention before one of opening steps 205, 210, or 215 was carried out.

In a step 235, the power consumption of device 100 is changed. For this purpose, a functional part of device 100, which is initially out of operation, is typically put into operation or, in an alternative specific embodiment, an element of device 100 which is in operation is taken out of operation. The change of the power consumption may also be produced by a change of the stress of an element of device 100. For example, a digital microprocessor may intentionally be employed to increase the power consumption or may be released from employment to reduce the power consumption.

In a following step 240, a second voltage at connectors 110 of device 100 is determined. Preferably, in a step 245, the change of the power consumption from step 235 is reversed immediately after the determination of the second voltage, in order to not influence normal operation of device 100 longer than necessary. The change back in step 245 may also be performed at any later point in time.

The second voltage is converted into a digital value with the aid of analog-digital converter 165 in a step 250 and stored in digital form in a step 255. Step 255 may be omitted if the second voltage is not further processed. In a step 260, a difference between the digital values of the first and the second voltages is determined. The difference is subsequently compared to a predetermined amount in a step 256. The predetermined amount is preferably permanently stored inside control device 160 or processing unit 170. In an alternative specific embodiment, the predetermined amount may also be determined algorithmically on the basis of absolute values of the power consumption of device 100 before and after its change in step 235, for example.

In step 270, a signal which reflects the result of the check of electrical connection 115 is output as a function of the result of the comparison in step 256. In one specific embodiment, it is an electrical signal. In another specific embodiment, it is a message which is transmitted via communication connection 130 to control unit 125, for example. In still another specific embodiment, it is a visual, acoustic, or haptic signal which is output with the aid of interface 180 to an operator, in particular a driver of motor vehicle 105, for example.

What is claimed is:

1. An electrical device, comprising:
connectors for an electrical connection to a voltage source;
a sampling device to determine a voltage applied to the connectors;
a controllable load to change an electrical power consumption of the device at the connectors; and
a control device configured to determine a degradation of the electrical connection if voltages, which are applied to the connectors at different electrical power consumptions, differ from one another by more than a predetermined amount.

2. The device as recited in claim 1, wherein the electrical connection includes a plug connection and the degradation includes a corrosion of the plug connection.

3. The device as recited in claim 1, wherein the electrical connection includes an electromechanical interruption element and the degradation includes wear of the interruption element.

4. The device as recited in claim 1, wherein the controllable load includes a switchable electrical resistor.

5. The device as recited in claim 4, wherein the device is a radar sensor for use on a motor vehicle and the electrical resistor includes a heatable radar lens of the radar sensor.

6. A method for detecting a degradation of an electrical connection between a voltage source and connectors of an electrical device, comprising:
determining a first voltage, which is applied to the connectors of the electrical device;
changing an electrical power consumption of the device at the connectors;
determining a second voltage, which is applied to the connectors of the electrical device; and
detecting the degradation if the first and second voltages differ from one another by more than a predetermined amount.

7. The method as recited in claim 6, wherein the first and second voltages are converted into a digital form and are compared to one another in the digital form.

8. The method as recited in claim 6, further comprising:
receiving a signal which triggers the method from a control unit connectable to the device.

9. The method as recited in claim 8, further comprising:
outputting a signal indicating the degradation to a further control unit.

10. A computer-readable data carrier storing a computer program code for detecting a degradation of an electrical connection between a voltage source and connectors of an electrical device, the computer program code, when executed on a processor, causing the processor to perform the steps of:
determining a first voltage, which is applied to the connectors of the electrical device;
changing an electrical power consumption of the device at the connectors;
determining a second voltage, which is applied to the connectors of the electrical device; and
detecting the degradation if the first and second voltages differ from one another by more than a predetermined amount.
